(19) United States
(12) Patent Application Publication
(10) Pub. No.: US 2009/0051041 A1
(43) Pub. Date: Feb. 26, 2009

(54) MULTILAYER WIRING SUBSTRATE AND METHOD FOR MANUFACTURING THE SAME, AND SUBSTRATE FOR USE IN IC INSPECTION DEVICE AND METHOD FOR MANUFACTURING THE SAME

(75) Inventors: Yuma Otsuka, Aichi (JP); Takakuni Nasu, Aichi (JP); Masanori Kito, Aichi (JP)

Correspondence Address: SUGHRUE MION, PLLC, 2100 PENNSYLVANIA AVENUE, N.W., SUITE 800, WASHINGTON, DC, 20037, US

(73) Assignee: NGK SPARK PLUG CO., LTD., Nagoya (JP)

(21) Appl. No.: 12/194,849

(22) Filed: Aug. 20, 2008

(30) Foreign Application Priority Data
Aug. 24, 2007 (JP) 2007-219073

(51) Int. Cl. H01L 23/48; H01L 21/44

(52) U.S. Cl. 257/774; 438/667; 257/E23.01; 257/E21.476

(57) ABSTRACT

A multilayer wiring substrate includes one or more resin dielectric layers (81), conductor layers (84), via conductors (91), and projecting portions (85). The one or more resin dielectric layers (81) individually having via holes (90) formed therein and extending through a first surface (82) and a second surface (83). The conductor layers (84) are formed from a conductive metal material and disposed on the first surface (82) of the one or more resin dielectric layers (81). The via conductors (91) are disposed in the respective via holes (90) and electrically connected to respective conductor layers (84). The projecting portions (85) are bent toward the main surface (72) or the back surface (73) of the multilayer wiring substrate, project from opening edges of respective via holes (90) toward center axes thereof, and penetrate into the respective via conductors (91).

### BACKGROUND OF THE INVENTION

1. Field of the Invention

The present invention relates to a multilayer wiring substrate and a method for manufacturing the same, and to a substrate for use in an IC inspection device for electrically inspecting an IC and a method for manufacturing the same.

2. Description of the Related Art

An example of a conventional multilayer wiring substrate is a resin wiring substrate having dielectric resin layers formed from resin. Various methods for manufacturing a resin wiring substrate have been proposed. Particularly, a method employing batch lamination is widely used (refer to, for example, Patent Documents 1 and 2). According to this method, a plurality of resin films on which respective circuits are formed (specifically, resin films on which respective conductor layers are formed and in which via conductors are formed) are laminated and then compression-bonded, to thereby form a resin wiring substrate. Thus, the number of manufacturing steps can be reduced. In the case where via conductors are formed by filling via holes with a conductive metal paste, the structures shown in FIGS. 17 to 19 are primarily employed for connecting the conductor layers. In the structure shown in FIG. 17, a via conductor 102 is in surface contact with the front surface of a lower conductor layer 101, and the side surface of the via conductor 102 is in surface contact with the end surface of an upper conductor layer 103, whereby the two conductor layers 101 and 103 are electrically connected. In the structure shown in FIG. 18, the via conductor 102 is in surface contact with the front surface of the lower conductor layer 101 and the back surface of the upper conductor layer 103, whereby the two conductor layers 101 and 103 are electrically connected. In the structure shown in FIG. 19, a through-hole conductor 104 is formed for conductively connecting the lower conductor layer 101 and the upper conductor layer 103, and the interior of the through-hole conductor 104 is filled with the via conductor 102, whereby the two conductor layers 101 and 103 are electrically connected.

[Patent Document 1] Japanese Patent Application Laid-Open (kokai) No. 2007-35717 (FIG. 1, etc.)

[Patent Document 2] Japanese Patent Application Laid-Open (kokai) No. 2004-363325 (FIG. 1, etc.)

3. Problems to Be Solved by the Invention

However, the connection reliability of the structure shown in FIG. 17 presents a problem in that the contact area between the via conductor 102 and the upper conductor layer 103 is small. The structures shown in FIGS. 18 and 19 provide high connection reliability, since sufficient contact area is provided between the via conductor 102 and the conductor layer 103. However, in forming the structure shown in FIG. 18, a via hole 105 for the via conductor 102 is formed in a state where the conductor layer 103 is present. Thus, the via hole 105 cannot assume the form of a through-hole opening at a surface of the board. As a result, the via hole 105 must be desmeared using, for example, a chemical solution or a plasma asher such that the manufacturing process is made complex. Also, in forming the structure shown in FIG. 19, not only a step for forming the via conductor 102, but also a step for forming the through-hole conductor 104 is required. This also results in a complex manufacturing process.

### SUMMARY OF THE INVENTION

The present invention has been achieved in consideration of the above-mentioned problems, and an object thereof is to provide a multilayer wiring substrate having high connection reliability between a via conductor and a conductor layer, and a substrate for use in an IC inspection device incorporating the multilayer wiring substrate. Another object of the invention is to provide a method for manufacturing, in a simple process, a multilayer wiring substrate having high connection reliability between a via conductor and a conductor layer, and a method for manufacturing a substrate for use in an IC inspection device incorporating the multilayer wiring substrate.

In a first aspect, the above objects of the invention have been achieved by providing a multilayer wiring substrate which has a main surface and a back surface and in which a plurality of main-surface-side terminals are formed on the main surface, the multilayer wiring substrate comprising: one or more resin dielectric layers individually having a first surface and a second surface and having via holes formed therein and extending through the first surface and the second surface; conductor layers formed from a conductive metal material and disposed on at least one of the first surface and the second surface of the one or more resin dielectric layers; and via conductors disposed in the respective via holes and electrically connected to the respective conductor layers, wherein the conductor layers have projecting portions that are bent toward the main surface or the back surface, said projecting portions projecting from opening edges of the respective via holes toward center axes thereof, and penetrating into the respective via conductors.

According to the above-mentioned first aspect, the projecting portions of the conductor layers penetrate into the respective via conductors. Thus, individual ones of the via conductors are in contact with not only an end surface of the corresponding projecting portion but also a surface of the projecting portion located on a side toward the main surface and a surface of the projecting portion located on a side toward the back surface. Therefore, the contact area between the via conductor and the projecting portion is increased, thereby enhancing connection reliability and lowering the resistance of circuits composed of the via conductors and the conductor layers. Further, durability and impact resistance are improved. Therefore, the life of the multilayer wiring substrate can be extended.

In a second aspect, the above objects of the invention have been achieved by providing a multilayer wiring substrate which has a main surface and a back surface and in which a plurality of main-surface-side terminals are formed on the main surface, the multilayer wiring substrate comprising: one or more resin dielectric layers individually having a first surface and a second surface and having via holes formed therein and extending through the first surface and the second surface; conductor layers formed from a conductive metal material and disposed on at least one of the first surface and the second surface of the one or more resin dielectric layers; and via conductors disposed in the respective via holes and electrically connected to the respective conductor layers, wherein the conductor layers have projecting portions that are bent toward the main surface or the back surface, said projecting portions projecting from opening edges of the respective via holes toward center axes thereof. Further, in the multilayer wiring substrate, the via conductors have respective groove portions on their side surfaces, and the projecting portions of the conductor layers are fitted into the respective groove portions.

In a third aspect, the above objects of the invention have been achieved by providing a multilayer wiring substrate which has a main surface and a back surface and in which a plurality of main-surface-side terminals are formed on the main surface, the multilayer wiring substrate comprising: one or more resin dielectric layers individually having a first surface and a second surface and having via holes formed therein and extending through the first surface and the second surface; conductor layers formed from a conductive metal material and disposed on at least one of the first surface and the second surface of the one or more resin dielectric layers; and via conductors disposed in respective via holes and electrically connected to respective conductor layers, wherein the conductor layers have projecting portions projecting from opening edges of the respective via holes toward center axes thereof. In the multilayer wiring substrate, the via conductors have respective groove portions on their side surfaces, and the projecting portions of the conductor layers are fitted into the respective groove portions.

According to the above-mentioned second and third aspects, the projecting portions of the conductor layers are fitted into the respective groove portions of the via conductors. Thus, individual ones of the via conductors can be in contact with an end surface of the corresponding projecting portion, a surface of the projecting portion located on a side toward the main surface, and a surface of the projecting portion located on a side toward the back surface. In this manner, the contact area between the via conductor and the projecting portion is increased, thereby enhancing connection reliability and lowering the resistance of circuits composed of the via conductors and the conductor layers. Further, durability and impact resistance are improved. Therefore, the life of the multilayer wiring substrate can be extended.

A plurality of the main-surface-side terminals of the multilayer wiring substrate are formed on the main surface of the multilayer wiring substrate. No particular limitation is imposed on the shape of the respective main-surface-side terminals as viewed in the thickness direction of the multilayer wiring substrate. Examples of the shape include a generally circular shape, a generally rectangular shape, and a generally triangular shape. The number and layout of the main-surface-side terminals are determined as appropriate according to the intended application of the multilayer wiring substrate. For example, when the multilayer wiring substrate is adapted for use in an IC inspection device, the number and layout of the main-surface-side terminals are determined according to the terminals of an IC to be inspected.

Examples of a preferred resin material used to form the resin dielectric layers include PI resin (polyimide resin), EP resin (epoxy resin), BT resin (bismaleimide triazine resin), PPE resin (polyphenylene ether resin), fluorine-containing resin, and silicone resin. Additionally, composite materials of any of the resins and nonwoven glass fabric, and composite materials of any of the resins and organic fiber, such as polyamide fiber, may be used. Also, the resin dielectric layer has via holes formed therein and extending through the first surface and the second surface. No particular limitation is imposed on the shape of a cross section of the respective via holes taken perpendicular to the thickness direction of the resin dielectric layer. However, a generally circular shape is preferred.

The conductor layers of the multilayer wiring substrate are disposed on at least one of the first surface and the second surface of individual ones of the resin dielectric layers. No particular limitation is imposed on a conductive metal material used to form the conductor layers. However, for example, the conductor layers can be of one or more conductive metal materials selected singly or in combination from among copper, aluminum, gold, silver, platinum, palladium, nickel, tin, lead, titanium, tungsten, molybdenum, tantalum, niobium, etc. Particularly, of the above-listed conductive metal materials, copper is preferred as a conductive metal material used to form the conductor layers. This is because copper exhibits excellent conductivity as compared with other conductive metal materials. Further, preferably, the conductor layers are formed from a metal foil or a metal sheet. Particularly, since a “foil” formed by rolling has densely aggregated crystals, the conductor layers formed from the foil exhibit high conductivity.

The projecting portions of the conductor layers are bent toward the main surface or the back surface and project from opening edges of the respective via holes toward center axes thereof. Preferably, the amount of projection of individual ones of the projecting portion as measured from the opening edge of the via hole is 1/20 to ⅓, inclusive, the diameter of the via hole. If the projection amount is less than 1/20 the diameter of the via hole, the contact area between the projecting portion and the via conductor is reduced, potentially resulting in a failure to maintain connection between the via conductor and the conductor layer. If the projection amount is in excess of ⅓ the diameter of the via hole, a portion of the via conductor into which the projecting portion penetrates (a portion of the via conductor where a groove portion is formed) becomes excessively thin, causing potential breakage of the via conductor upon being subjected to impact. No particular limitation is imposed on the angle of bend of the projecting portion; i.e., the angle between the projecting portion and the first surface (and the second surface) of the resin dielectric layer. However, preferably, the angle is 1° to 30° inclusive.

Respective projecting portions of the conductor layer may penetrate into the side surface of the corresponding via conductor along the entire circumference or along a part of the circumference thereof. Preferably, the projecting portion penetrates into the side surface of the via conductor along the entire circumference thereof. This is because the contact area between the projecting portion and the via conductor becomes larger, thereby further enhancing connection reliability.

The via conductors of the multilayer wiring substrate are disposed in the respective via holes. The via conductors establish electrical conduction between conductors of different layers. Specifically, the via conductors are electrically connected to the conductor layers. No particular limitation is imposed on a material used to form the via conductors. However, for example, the material can be one or more metals selected singly or in combination from among copper, gold, silver, platinum, palladium, nickel, tin, lead, titanium, tungsten, molybdenum, tantalum, niobium, etc. An example of a conductive metal composed of two or more metals is solder, which is an alloy of tin and lead. A conductive metal for use as a via conductor material composed of two or more metals can also be a lead-free solder (e.g., Sn—Ag solder, Sn—Ag—Cu solder, Sn—Ag—Bi solder, Sn—Ag—Bi—Cu solder, Sn—Zn solder, or Sn—Zn—Bi solder). Preferably, the via conductors are composed of a cured product of a conductive metal paste formed by a process of mixing particles of the above-mentioned conductive metal in an organic material and then curing the resultant mixture, or of an agglomerate of conductive metal particles which contains no or almost no organic material.

Preferably, the via conductors have flat end surfaces located opposite a side toward which the projecting portions of the conductor layers are bent. With this structure, the end surfaces of the via conductors can be readily made flush with the surfaces of the respective conductor layers, whereby the surface roughness on a side of the resin dielectric layer where the conductor layers are present is lessened. Therefore, since a plurality of the resin dielectric layers can be reliably laminated, the probability of the multilayer wiring substrate becoming defective is further decreased.

Preferably, the respective via conductors have a structure in which a first large-diameter portion (hereinafter also referred to as the primary large-diameter portion) disposed in the corresponding via hole and a second large-diameter portion (hereinafter also referred to as the secondary large-diameter portion) are connected together via a small-diameter portion, and the primary large-diameter portion and the secondary large-diameter portion are arranged to hold the corresponding projecting portion of the conductor layer therebetween across the thickness of the projecting portion. By employing such a structure, the primary large-diameter portion and the secondary large-diameter portion reliably come into contact with a surface of the projecting portion located on a side toward the back surface and a surface of the projecting portion located on a side toward the main surface, respectively. Therefore, the contact area between the via conductor and the projecting portion can be reliably ensured, whereby connection reliability is enhanced.

No particular limitation is imposed on the shape of the respective via conductors (primary large-diameter portion, small-diameter portion, and secondary large-diameter portion) as viewed in the thickness direction of the multilayer wiring substrate. However, a generally circular shape is preferred. In this case, preferably, the primary large-diameter portion and the secondary large-diameter portion have an outside diameter of 30 μm to 200 μm inclusive. The small-diameter portion must be smaller in outside diameter than the primary large-diameter portion and the secondary large-diameter portion and has an outside diameter of, preferably, 15 μm to 195 μm inclusive.

Preferably, the thickness of the primary large-diameter portion is greater than that of the secondary large-diameter portion and is substantially equal to that of the resin dielectric layer. If the thickness of the primary large-diameter portion is greater than that of the resin dielectric layer, the primary large-diameter portion projects from the first or second surface of the resin dielectric layer, thereby causing a rough surface. As a result, laminating a plurality of the resin dielectric layers becomes difficult, thereby increasing a probability that the multilayer wiring substrate becomes defective. Also, since the length of the via conductor increases, resistance increases accordingly. If the thickness of the primary large-diameter portion is smaller than that of the resin dielectric layer, the end surface of the primary large-diameter portion opposite a side associated with the small-diameter portion does not reach the first or second surface of the resin dielectric layer. As a result, the via conductor fails to be connected to the conductor layer formed on the adjacent resin dielectric layer. Thus, connection reliability is decreased.

Further, preferably, the end surface of the secondary large-diameter portion is flush with the surface of the conductor layer. With this structure, surface roughness on a side of the resin dielectric layer where the conductor layers and the secondary large-diameter portions are present is lessened. Thus, since a plurality of the resin dielectric layers can be reliably laminated, the probability of the multilayer wiring substrate becoming defective is further decreased. If the end surface of the secondary large-diameter portion is not flush with the surface of the corresponding conductor layer, surface roughness on a side of the resin dielectric layer where the conductor layers and the secondary large-diameter portions are present becomes excessive. Therefore, laminating a plurality of the resin dielectric layers becomes difficult, thereby increasing the probability of the multilayer wiring substrate becoming defective.

In a fourth aspect, the present invention provides a substrate for use in an IC inspection device, comprising a multilayer wiring substrate of any one of the above-mentioned first to third aspects, and a ceramic multilayer wiring substrate bonded to a back surface of the multilayer wiring substrate for supporting the multilayer wiring substrate, and electrically connected to the multilayer wiring substrate, the substrate being configured such that a plurality of conductive metal probes can repeatedly come into contact with (i.e., releasably engage) the plurality of main-surface-side terminals, respectively, of the multilayer wiring substrate.

In a fifth aspect, the present invention provides a substrate for use in an IC inspection device, comprising a multilayer wiring substrate of any one of the above-mentioned first to third aspects; a ceramic multilayer wiring substrate bonded to a back surface of the multilayer wiring substrate for supporting the multilayer wiring substrate, and electrically connected to the multilayer wiring substrate; and a plurality of probe pins formed from a conductive metal, attached to the plurality of main-surface-side terminals, respectively, of the multilayer wiring substrate, and adapted to come into contact with respective terminals of an IC.

According to the fourth or fifth aspects, a multilayer wiring substrate having a high connection reliability between the via conductors and the conductor layers is used as a substrate for an IC inspection device. Accordingly, the substrate for use in an IC inspection device exhibits high connection reliability. Also, since the projecting portions of the conductor layers penetrate into the respective via conductors, a problem (e.g., falling-off of the via conductor(s)) caused by impact to the main-surface-side terminals when conductive metal probes repeatedly contact the respective main-surface-side terminals, or repeated impact to the main-surface-side terminals through respective probe pins which come into contact with an IC, can be prevented. Therefore, the life of the multilayer wiring substrate and in turn the life of the substrate for use in an IC inspection device can be extended.

The ceramic multilayer wiring substrate of the fourth or fifth aspects is a laminate of, for example, ceramic layers. A specific example of the ceramic used as a main material for the ceramic multilayer wiring substrate is a sintered body of a high-temperature-fired ceramic, such as alumina, aluminum nitride, boron nitride, silicon carbide, or silicon nitride. Another example is a sintered body of a low-temperature-fired ceramic, such as glass ceramic formed by adding an inorganic filler, such as alumina, to borosilicate glass or lead borosilicate glass.

In a sixth aspect, the present invention provides a method for manufacturing a multilayer wiring substrate of any one of the first to third aspects, which comprises: a drilling step for drilling via holes through a resin film having a first surface and a second surface, the first surface being clad with a metal foil, and forming projecting portions of the metal foil projecting from opening edges of the respective via holes toward center axes thereof, by irradiating the resin film with a laser beam from a side of the second surface; a patterning step for selectively removing the metal foil with the projecting portions left intact, so as to form conductor layers; a via-conductor-forming step for filling a conductive metal paste into the via holes from a side of the first surface so as to form via conductors; and a laminating-and-compression-bonding step for laminating a plurality of the resin films which have undergone the via-conductor-forming step, and compression-bonding together the plurality of the resin films.

According to the manufacturing method of the sixth aspect, in a state where the via holes and the projecting portions of the conductor layers are formed, the via-conductor-forming step is carried out for forming the via conductors; thus, the projecting portions penetrate into the respective via conductors. Consequently, the respective via conductors are in contact with not only an end surface of a corresponding projecting portion but also a surface of the projecting portion located on a side toward the main surface and a surface of the projecting portion located on a side toward the back surface. In this manner, the contact area between the via conductor and the projecting portion is increased, thereby enhancing connection reliability.

In the drilling step, the metal-foil-clad resin film is irradiated with a laser beam so as to form holes which extend through the resin film and the metal foil. In this manner, the need to desmear the via holes by use of, for example, a chemical solution or a plasma asher is eliminated. Further, a step for forming through-hole conductors is not required, so that the process for manufacturing the multilayer wiring substrate can be simplified.

In the drilling step, if the resin film is irradiated with a laser beam from a side of the first surface, the energy of the laser beam is consumed mostly for drilling the metal foil, which is impenetrable to light. Thus, the laser beam encounters difficulty in reaching beyond the metal foil. As a result, a hole greater in diameter than the via hole is formed in the metal foil; i.e., the projecting portion cannot be formed. By contrast, according to the manufacturing method of the sixth aspect, in the drilling step, the resin film is irradiated with a laser beam from a side of the second surface. Accordingly, the energy of the laser beam is first used to drill the resin film, which is penetrable to light, before drilling the metal foil, such that a via hole having a large diameter is easily formed. As a result, a hole smaller in diameter than the via hole is formed in the metal foil. In this manner which allows for the formation of a smaller-diameter hole in the metal foil, a projecting portion of the metal foil projecting toward the center axis of the via hole from the opening edge of the via hole is formed. That is, while the via hole is formed, the projecting portion of the metal foil can be reliably formed.

In the laminating-and-compression-bonding step, a force is applied across the thickness direction of the resin films, whereby the projecting portions of the conductor layers can be bent toward the main surface or the back surface, and end surfaces of the via conductors located opposite a side toward which the projecting portions of the conductor layer are bent can be made flat. In association with this, roughness on the main surface of the multilayer wiring substrate is lessened, so that a plurality of main-surface-side terminals can be reliably formed on the main surface. Therefore, the probability of the multilayer wiring substrate becoming defective is decreased, thereby improving yield.

The patterning step may be carried out before the via-conductor-forming step, or the via-conductor-forming step may be carried out before the patterning step. However, preferably, the patterning step is carried out before the via-conductor-forming step. If the via-conductor-forming step is carried out before the patterning step, the conductive metal paste projects from the first surface, causing a rough surface. Accordingly, even when a patterning film is affixed onto the metal foil in the patterning step, film releasability is impaired, resulting in deteriorated workability.

Preferably, in laser irradiation of the drilling step, the laser beam is focused on a position located short of the second surface of the resin film. In this manner, the energy of the laser beam in the vicinity of the first surface is slightly weakened, whereby a hole smaller in diameter than the via hole can be readily formed in the metal foil (i.e., the projecting portion can be readily formed).

Lasers usable for the laser irradiation include a UV laser, such as a YAG laser, and a carbon dioxide laser. However, the YAG laser is preferred. The carbon dioxide laser performs processing through heat melting and is thus inferior to the YAG laser in workability. Specifically, when the carbon dioxide laser is used, the resin film is melted to a greater extent than required. Thus, forming a small-diameter via hole is difficult. Also, the wavelength of a laser beam from the carbon dioxide laser is such that the laser beam is reflected by the surface of a copper foil. Thus, the laser beam encounters difficulty in penetrating the copper foil. Further, in forming a via hole, the amount of residual resin is large. For example, in the case where carbon dioxide laser irradiation is carried out in such a manner that a laser beam penetrates the resin film only, and does not penetrate the copper foil, the thickness of resin remaining in the via hole (on the surface of the copper foil) is generally 2 μm. By contrast, the YAG laser performs processing through molecular decomposition and thus exhibits excellent processability. That is, as compared with the case of using the carbon dioxide laser, a laser beam from the YAG laser can form the via hole accurately and can reliably penetrate the copper foil. Also, the amount of residual resin in a formed via hole is small. For example, in the case where YAG laser irradiation is carried out in such a manner that a laser beam penetrates the resin film but does not penetrate the copper foil, the thickness of resin remaining in the via hole (on the surface of the copper foil) is generally 0.5 μm.

The metal foil is used to form the conductor layers and therefore is generally made of the same conductive metal material as that of the conductor layers. No particular limitation is imposed on the metal foil. However, for example, the metal foil can comprise one or more conductive metal materials selected singly or in combination from among copper, aluminum, gold, silver, platinum, palladium, nickel, tin, lead, titanium, tungsten, molybdenum, tantalum, niobium, etc. Particularly, of the above-listed conductive metal materials, copper is preferred. Namely, the metal foil is preferably a copper foil, because copper exhibits excellent conductivity as compared with the other conductive metal materials. Also, the aforementioned conductive metal paste is used to form the via conductors, and therefore is generally made of the same material as that of the via conductors. No particular limitation is imposed on the material used to form the conductive metal paste. However, for example, the material can comprise one or more metals selected singly or in combination from among copper, gold, silver, platinum, palladium, nickel, tin, lead, titanium, tungsten, molybdenum, tantalum, niobium, etc. Particularly, the conductive metal paste is preferably a silver paste prepared by mixing silver particles, which are resistant to oxidation, in epoxy resin. Use of the silver paste lowers the resistance of the via conductors, and ensures connection integrity between the via conductors and the corresponding projecting portions of the conductor layers.

In a seventh aspect, the above-noted objectives of the invention are achieved by providing a method for manufacturing a substrate for use in an IC inspection device of the fourth or fifth aspects, which comprises: a drilling step for drilling via holes through a resin film having a first surface and a second surface, the first surface being clad with a metal foil, and forming projecting portions of the metal foil projecting from opening edges of the respective via holes toward center axes thereof, by irradiating the resin film with a laser beam from a side of the second surface; a patterning step for selectively removing the metal foil with the projecting portions left intact, so as to form conductor layers; a via-conductor-forming step for filling a conductive metal paste into the via holes from a side of the first surface so as to form via conductors; and a laminating-and-compression-bonding step for laminating a plurality of the resin films which have undergone the via-conductor-forming step, on a main surface of a ceramic multilayer wiring substrate, and compression-bonding together the plurality of the resin films and the ceramic multilayer wiring substrate.

According to the manufacturing method of the seventh aspect, in a state where the via holes and the projecting portions of the conductor layers are formed, the via-conductor-forming step is carried out so as to form the via conductors. In this manner, the projecting portions penetrate into the respective via conductors thus formed. Thus, each of the via conductors is in contact with not only an end surface of the corresponding projecting portion but also a surface of the projecting portion located on a side toward the main surface and a surface of the projecting portion located on a side toward the back surface. Accordingly the contact area between the via conductor and the projecting portion is increased, thereby enhancing connection reliability. Also, in the drilling step, by means of laser irradiation, holes which extend through the resin film and the metal foil are formed. In this manner, the need to desmear the via holes by use of, for example, a chemical solution or a plasma asher is eliminated. Further, a step for forming through-hole conductors is not required, so that the process for manufacturing the multilayer wiring substrate can be simplified.

### BRIEF DESCRIPTION OF THE DRAWINGS

FIG. 1 is a schematic view, as viewed from the back-surface side, showing a substrate for use in an IC inspection device according to an embodiment of the present invention.

FIG. 2 is a schematic view, as viewed from the main-surface side, showing the substrate for use in an IC inspection device.

FIG. 3 is a schematic view sectional view showing the substrate for use in an IC inspection device.

FIG. 4 is an enlarged sectional view showing essential portions of a multilayer wiring substrate.

FIG. 5 is an enlarged photo showing projecting portions of the multilayer wiring substrate.

FIG. 6 is an enlarged sectional view of an intermediate, in a method for manufacturing the substrate for use in an IC inspection device.

FIG. 7 is an enlarged sectional view of an intermediate, in the method for manufacturing the substrate for use in an IC inspection device.

FIG. 8 is an enlarged sectional view of an intermediate, in the method for manufacturing the substrate for use in an IC inspection device.

FIG. 9 is an enlarged sectional view of an intermediate, in the method for manufacturing the substrate for use in an IC inspection device.

FIG. 10 is a schematic sectional view illustrating a method for manufacturing the substrate for use in an IC inspection device.

FIG. 11 is a schematic sectional view illustrating a method for manufacturing the substrate for use in an IC inspection device.

FIG. 12 is a schematic sectional view illustrating a step in a method for manufacturing the substrate for use in an IC inspection device according to another embodiment of the present invention.

FIG. 13 is a schematic sectional view illustrating a step in the method for manufacturing the substrate for use in an IC inspection device according to another embodiment of the present invention.

FIG. 14 is a schematic sectional view illustrating a step in the method for manufacturing the substrate for use in an IC inspection device according to another embodiment of the present invention.

FIG. 15 is an enlarged schematic sectional view of a substrate for use in an IC inspection device according to another embodiment of the present invention.

FIG. 16 is a schematic sectional view of a substrate for use in an IC inspection device according to a further embodiment of the present invention.

FIG. 17 is an enlarged sectional view showing a portion of a conventional multilayer wiring board.

FIG. 18 is an enlarged sectional view showing a portion of a conventional multilayer wiring board.

FIG. 19 is an enlarged sectional view showing a portion of a conventional multilayer wiring board.

### DESCRIPTION OF REFERENCE NUMERALS

Reference numerals used to identify various structural features in the drawings include the following.
10, 10A, 10B: substrate for use in an IC inspection device
11: ceramic multilayer wiring substrate
61: conductive metal probe
65: probe pin
71, 71A: multilayer wiring substrate
72: main surface
73: back surface
74: main-surface-side terminal
81: resin dielectric layer
82: first surface
83: second surface
84: conductor layer
85: projecting portion
90: via hole
91: via conductor
92: side surface of via conductor
93: groove portion
95: primary large-diameter portion (first large-diameter portion)
96: small-diameter portion
97: secondary large-diameter portion (second large-diameter portion)
161: resin film
162: copper foil as metal foil

### DETAILED DESCRIPTION OF THE PREFERRED EMBODIMENTS

A substrate for use in an IC inspection device according to an embodiment of the present invention will next be described in detail with reference to the drawings. However, the present invention should not be construed as being limited thereto.

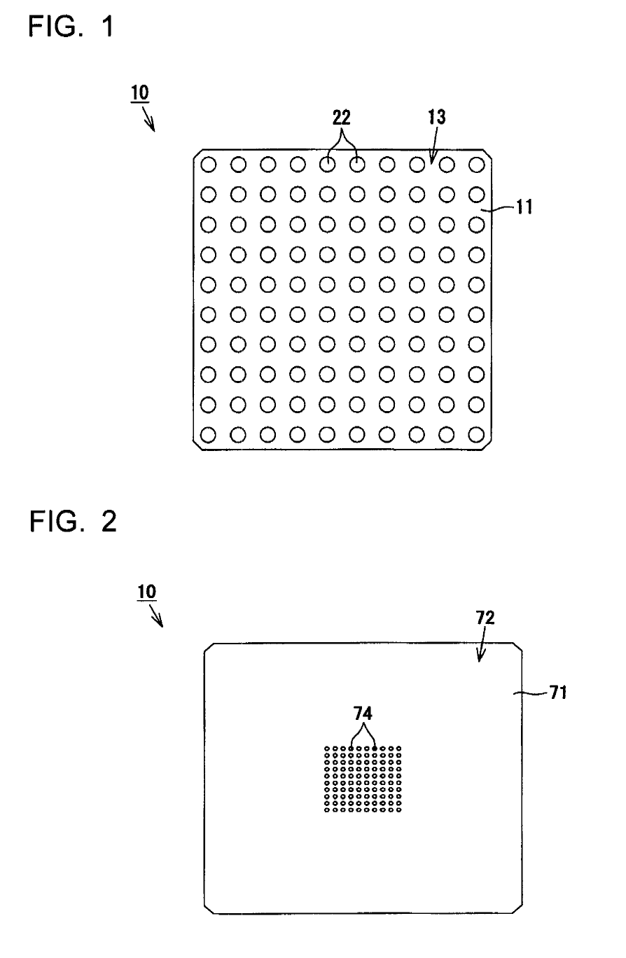

FIGS. 1 to 3 show a substrate 10 for use in an IC inspection device according to the present embodiment. The substrate 10 for use in an IC inspection device is a component of a device (an IC inspection jig) for electrically inspecting a silicon wafer on which a plurality of ICs are formed. The substrate 10 for use in an IC inspection device includes a multilayer wiring substrate 71 and a ceramic multilayer wiring substrate 11, which is electrically connected to the multilayer wiring substrate 71. The ceramic multilayer wiring substrate 11 is a sintered body of alumina (ceramic material) in which a plurality of ceramic layers 14 are laminated, and is a plate-like product having a generally square shape as viewed in plane. The ceramic multilayer wiring substrate 11 of the present embodiment has a length of one side of 65 mm and a thickness of 4.0 mm to 5.0 mm inclusive.

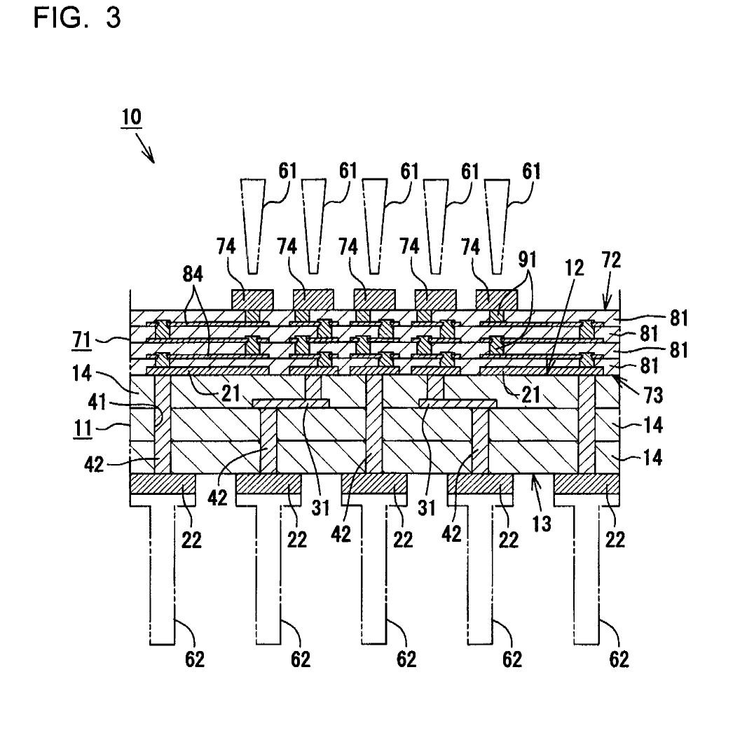

In the interior of the ceramic multilayer wiring substrate 11 shown in FIG. 3, a plurality of internal-layer electrodes 31, which are metallized layers of tungsten, are formed on the interface between the ceramic layers 14. A plurality of main-surface-side terminals 21 are formed on a main surface 12 of the ceramic multilayer wiring substrate 11 in substantially the entire region of the main surface 12. A plurality of back-surface-side terminals 22 are formed on a back surface 13 of the ceramic multilayer wiring substrate 11 in a lattice-like arrangement in substantially the entire region of the back surface 13 (see FIG. 1). In the present embodiment, individual ones of the main-surface-side terminals 21 and the back-surface-side terminals 22 assume a structure in which conductive metal thin-films of different kinds are laminated. Individual ones of the back-surface-side terminals 22 have a circular shape as viewed in plane and has a diameter of about 0.3 mm to 1.0 mm. Pins 62, which serve as external connection terminals of the IC inspection jig, are attached to a plurality of the back-surface-side terminals 22, respectively.

In the interior of the ceramic multilayer wiring substrate 11, a plurality of via holes 41 are formed in such a manner as to extend in the thickness direction of the ceramic multilayer wiring substrate 11. Individual ones of the via holes 41 have a generally circular cross-sectional shape and has a diameter of 100 μm. Via conductors 42 formed through tungsten metallization are disposed in a plurality of the via holes 41, respectively. The end surfaces of the via conductors 42 which are exposed on the back surface 13 are bonded to the respective back-surface-side terminals 22. In the interior of the ceramic multilayer wiring substrate 11, the via conductors 42 are bonded to corresponding internal-layer electrodes 31. Accordingly, a plurality of the via conductors 42 establish electrical connection between the internal-layer electrodes 31 and the corresponding back-surface-side terminals 22.

As shown in FIG. 3, the multilayer wiring substrate 71 has a main surface 72 and a back surface 73 and is a plate-like product having a generally square shape as viewed in plane. The multilayer wiring substrate 71 of the present embodiment has a length of one side of 65 mm and a thickness of 136 mm. In use, the multilayer wiring substrate 71 is disposed such that the main surface 72 faces a wafer (not shown) to be inspected. The ceramic multilayer wiring substrate 11 is bonded to the back surface 73 of the multilayer wiring substrate 71 so as to support the multilayer wiring substrate 71 from the side of the back surface 73.

A plurality of main-surface-side terminals 74 are formed on the main surface 72 of the multilayer wiring substrate 71 in a lattice-like arrangement in a central region (see FIG. 2). In the present embodiment, individual ones of the main-surface-side terminals 74 assume a structure in which conductive metal thin-films of different kinds are laminated. Individual ones of the main-surface-side terminals 74 have a circular shape as viewed in plane and have a diameter of about 0.3 mm to 0.5 mm. As shown in FIG. 3, a plurality of conductive-metal probes 61 which can come into contact with respective terminals of individual ICs formed on a wafer can repeatedly come into contact with and disconnect from the respective main-surface-side terminals 74.

As shown in FIGS. 3 to 5, the multilayer wiring substrate 71 has a structure in which first to fourth resin dielectric layers 81 (each having an exemplary thickness of 25 mm) are laminated. Individual ones of the resin dielectric layers 81 are formed primarily of a dielectric substrate of polyimide (UPILEX VT, a product of Ube Industries, Ltd.) and have a first surface 82 and a second surface 83. Individual ones of the resin dielectric layers 81 have a plurality of via holes 90 formed therein and extending through the first surface 82 and the second surface 83. Individual ones of the via holes 90 has a circular cross section and has a diameter of 100 μm.

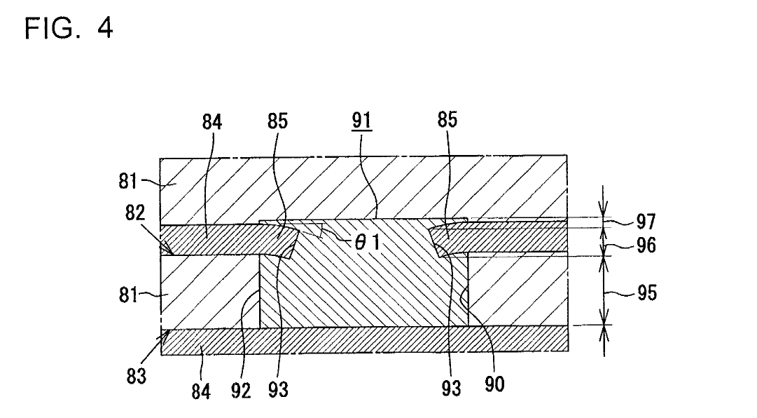

A plurality of conductor layers 84 (each having an exemplary thickness of 9 μm) of copper, which is a conductive metal material, are formed on the first surface of 82 of each of the resin dielectric layers 81. A portion of individual ones of the conductor layers 84 are formed into a projecting portion 85 which projects toward the center axis of the corresponding via hole 90 from the opening edge of the via hole 90. The amount of projection of the projecting portion 85 from the opening edge of the via hole 90 is about 1/10 of the diameter (100 μm) of the via hole 90; i.e., about 10 μm. The projecting portions 85 are bent toward the back surface 73 of the multilayer wiring substrate 71. An angle θ1 of bend of the projecting portion 85 (see FIG. 4); i.e., the angle between the projecting portion 85 and the first surface 82 of the resin dielectric layer 81, is about 15°.

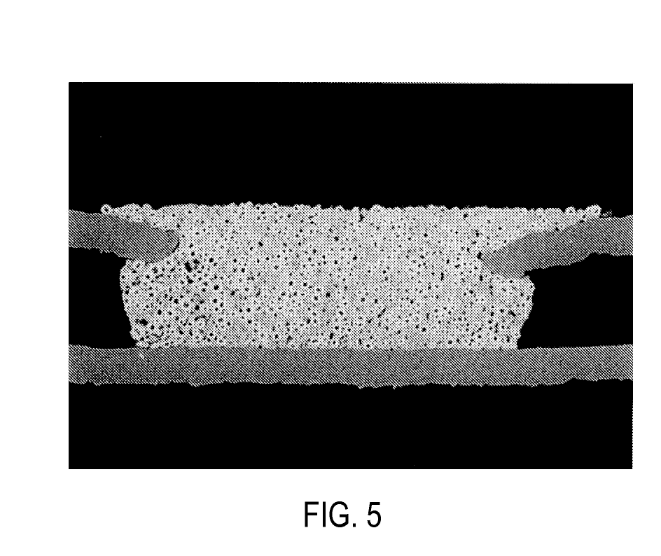

As shown in FIGS. 3 to 5, via conductors 91, which are cured products of a conductive metal paste; i.e., a silver paste (THR-500A, a product of Harima Chemicals, Inc.), are provided in the respective via holes 90. The silver paste is a mixture of an epoxy resin and a large number of silver particles (see FIG. 5). End surfaces of the via conductors 91 located on a side toward which the projecting portions 85 of the conductor layers 84 are bent (i.e., the end surfaces located on the side of the second surface 83), and end surfaces of the via conductors 91 located opposite a side toward which the projecting portions 85 of the conductor layers 84 are bent (i.e., the end surfaces located on the side of the first surface 82), are flat. Also, the via conductors 91 provided in the first to third resin dielectric layers 81 have respective groove portions 93 on their side surfaces 92 (see FIG. 4). As shown in FIG. 3, the via conductors 91 provided in the first resin dielectric layer 81 are such that their end surfaces on the side of the second surface 83 are electrically connected, through surface contact, to respective main-surface-side terminals 21, whereas their end portions on the side of the first surface 82 are electrically connected to respective conductor layers 84 formed on the first resin dielectric layer 81. The via conductors 91 provided in the second resin dielectric layer 81 are such that their end surfaces on the side of the second surface 83 are electrically connected, through surface contact, to respective conductor layers 84 formed on the first resin dielectric layer 81, whereas their end portions on the side of the first surface 82 are electrically connected to respective conductor layers 84 formed on the second resin dielectric layer 81. Similarly, the via conductors 91 provided in the third resin dielectric layer 81 are such that their end surfaces on the side of the second surface 83 are electrically connected, through surface contact, to respective conductor layers 84 formed on the second resin dielectric layer 81, whereas their end portions on the side of the first surface 82 are electrically connected to respective conductor layers 84 formed on the third resin dielectric layer 81. Further, the via conductors 91 provided in the fourth resin dielectric layer 81 are such that their end surfaces on the side of the second surface 83 are electrically connected, through surface contact, to respective conductor layers 84 formed on the third resin dielectric layer 81, whereas their end surfaces on the side of the first surface 82 are electrically connected, through surface contact, to respective main-surface-side terminals 74.

As shown in FIG. 4, individual ones of the via conductors 91 have a primary large-diameter portion 95 disposed in a corresponding via hole 90 and a secondary large-diameter portion 97 connected together to the primary large-diameter portion via a small-diameter portion 96. The large-diameter portions 95 and 97 and the small-diameter portion 96 have a circular cross section. In the present embodiment, the large-diameter portions 95 and 97 have the same outside diameter; specifically, 100 μm. The small-diameter portion 96 has an outside diameter; specifically, of about 95 μm, smaller than that of the large-diameter portions 95 and 97. The primary large-diameter portion 95 is thicker than the secondary large-diameter portion 97 and has a thickness substantially equal to the thickness (25 mm) of the resin dielectric layer 81.

The primary large-diameter portion 95 and the secondary large-diameter portion 97 are arranged so as to hold corresponding projecting portion 85 of the conductor layer 84 therebetween across the thickness direction of the projecting portion 85. That is, the projecting portion 85 penetrates into the side surface 92 of the via conductor 91. The projecting portion 85 penetrates into the side surface 92 of the via conductor 91 along the entire circumference of the side surface 92. Since the end surface of the primary large-diameter portion 95 located on a side toward the secondary large-diameter portion 97, the end surface of the secondary large-diameter portion 97 located on a side toward the primary large-diameter portion 95, and the side surface of the small-diameter portion 96 define the groove portion 93, the projecting portion 85 can also be said to be fitted into the groove portion 93.

Next, a method for manufacturing the above-described substrate 10 for use in an IC inspection device will be described. First, the ceramic multilayer wiring substrate 11 is prepared beforehand. A method for manufacturing the ceramic multilayer wiring substrate 11 is described below.

### (1-1) Laminate Preparation Step

According to the manufacturing method, a ceramic laminate (not shown) having a required structure is prepared by a laminate preparation step described below.

a) First, a ceramic material; i.e., an alumina powder, an organic solvent, an organic binder, etc., are wet-mixed in a pot, thereby yielding a slurry used to form a green sheet. Next, by use of a known casting apparatus, the green-sheet-formation slurry is cast thinly and uniformly on a predetermined sheet. Subsequently, the slurry cast into a sheet-like form is dried by heating, thereby yielding a green sheet. In place of such a sheet-forming process, a press-forming process may be employed for forming a similar green sheet. The green sheet thus prepared is cut into a plurality of green sheets each having a predetermined length.

b) Next, the thus-obtained plurality of green sheets are subjected to laser irradiation, punching, drilling, or a like process so as to form a large number of through-holes at respectively predetermined positions. In the green sheets which are to become the ceramic layers 14, the through-holes are formed at the positions of the via holes 41.

c) Next, an internal-layer-electrode-formation tungsten paste, which has been prepared beforehand, is applied through printing in a predetermined pattern to the drilled green sheets by use of a known paste printer. As a result, internal-layer-formation layers which are to become the internal-layer electrodes 31 are formed at respectively predetermined positions. Also, by use of a known paste-press-filling apparatus, a via-conductor-formation tungsten paste, which has been prepared beforehand, is press-filled into the through-holes which are to become the via holes 41. As a result, via-conductor-formation portions which are to become the via conductors 42 are formed in the respective via holes 41. Notably, the paste-pattern-printing step and the paste-press-filling step may be performed in reverse order.

d) After paste drying, a plurality of the green sheets are arranged in layers. A pressing force is applied to the resultant laminate in the sheet-layering direction so as to compression-bond the green sheets together for integration, thereby forming a ceramic laminate.

### (1-2) Debindering Step

After the laminate preparation step, the ceramic laminate is debindered in air at a temperature of 200° C. to 300° C. by heating for 20 to 60 hours, thereby removing binder contained in the ceramic laminate through decomposition. After debindering, the ceramic laminate is moved into a firing apparatus and is then fired at a temperature (about 1,600° C.) at which alumina can be sintered, by heating for about 24 hours. As a result, alumina, and tungsten contained in the paste are simultaneously sintered. By carrying out the firing process, the green sheets become the ceramic layers 14; the via-conductor-formation portions become the via conductors 42; and the internal-layer-formation layers become the internal-layer electrodes 31. The ceramic laminate is densified through sintering, whereby its mechanical strength is enhanced. Also, good electrical characteristics (insulating characteristic) are imparted to the ceramic laminate.

### (1-3) Polishing Step

Subsequently, using a known surface polisher, the main surface 12 and the back surface 13 of the sintered ceramic laminate (ceramic multilayer wiring substrate 11) are polished so as to enhance the flatness of the main and back surfaces 12 and 13. In the present embodiment, polishing is performed so as to attain a flatness of 150 μm or less and a surface roughness Ra of 0.2 μm or less.

### (1-4) Terminal-Forming Step

After the polishing step, the main-surface-side terminals 21, which are circular and of greater diameter than the via conductors 42, are formed on the end surfaces of respective via conductors 42 which are exposed at the main surface 12 of the ceramic multilayer wiring substrate 11. Similarly, the back-surface-side terminals 22, which are circular and of greater diameter than the via conductors 42, are formed on the end surfaces of the respective via conductors 42 which are exposed at the back surface 13 of the ceramic multilayer wiring substrate 11. A specific procedure for forming the terminals 21 and 22 is described below.

First, an underlying metal layer of a one-layer structure or a multilayer structure of one or more conductive metals is formed on the entire main surface 12 and the entire back surface 13 of the ceramic multilayer wiring substrate 11. Examples of the metal usable as the underlying metal include titanium, molybdenum, chromium, cobalt, tungsten, nickel, tantalum and niobium. The present embodiment employs an underlying metal layer which has a two-layer structure of titanium and molybdenum formed by sputtering. Next, in a state where a predetermined plating resist is applied onto the underlying metal layer, copper electroplating is performed, thereby forming a copper plating layer. Subsequently, the plating resist is removed, followed by etching for removing exposed portions of the underlying metal layer. As a result, a plurality of laminated metal portions each consisting of a titanium-sputtered layer, a molybdenum-sputtered layer, and a copper plating layer are formed on the end surfaces of respective via conductor 42 which are exposed at the main surface 12 and back surface 13 of the ceramic multilayer wiring substrate 11. Next, nickel electroplating is carried out so as to form nickel plating layers which cover the respective laminated metal portions. Further, gold electroplating is carried out so as to form gold plating layers which cover the respective nickel plating layers. As a result, the ceramic multilayer wiring substrate 11 having a plurality of the main-surface-side terminals 21 and a plurality of the back-surface-side terminals 22 is completed.

Next, a method for manufacturing the multilayer wiring substrate 71 will be described.

### (2-1) Drilling Step

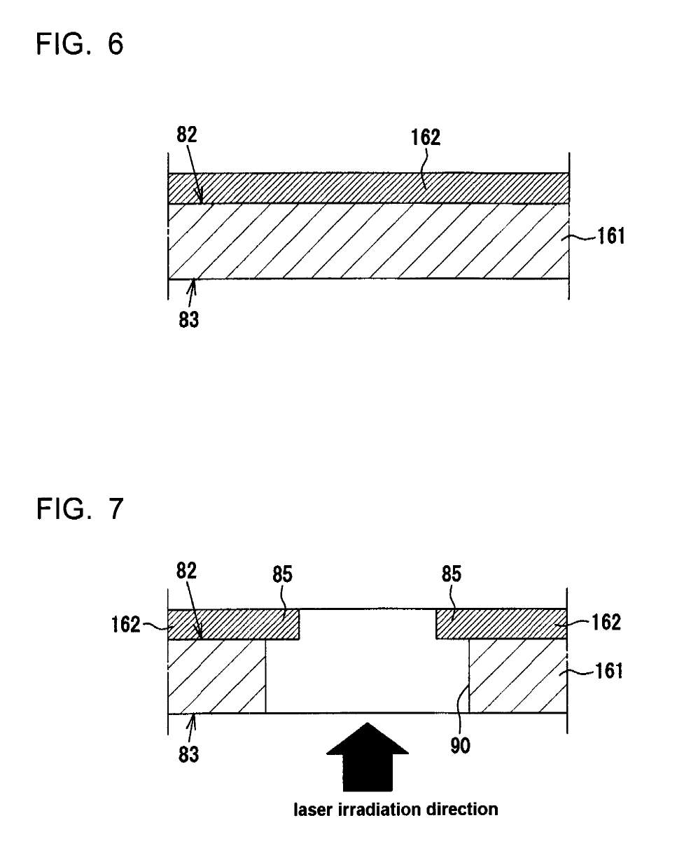

In the drilling step, a copper-foil-clad resin film is prepared, which is a resin film 161 which has a thickness of 25 μm and whose first surface 82 is clad with a copper foil 162 (metal foil) having a thickness of 9 μm (see FIG. 6). Next, the resin film 161 is subjected to laser irradiation from the second surface side 83 using a YAG laser (model 5150, a product of ESI Inc.) or the like. Specifically, laser irradiation is carried out such that a laser beam is focused on a position located short of the second surface 83 of the resin film 161 (in the present embodiment, a position located 0.75 mm short of the second surface 83) and such that the laser beam is circularly moved for trepanning. The laser output is about 0.3 W to 0.5 W.

In this manner, the via hole 90 extending through the resin film 161 is formed, together with the projecting portion 85 of the copper foil 162 projecting toward the center axis of the via hole 90 from the opening edge of the via hole 90 (see FIG. 7). The arrow in FIG. 7 indicates a laser irradiation direction.

### (2-2) Patterning Step

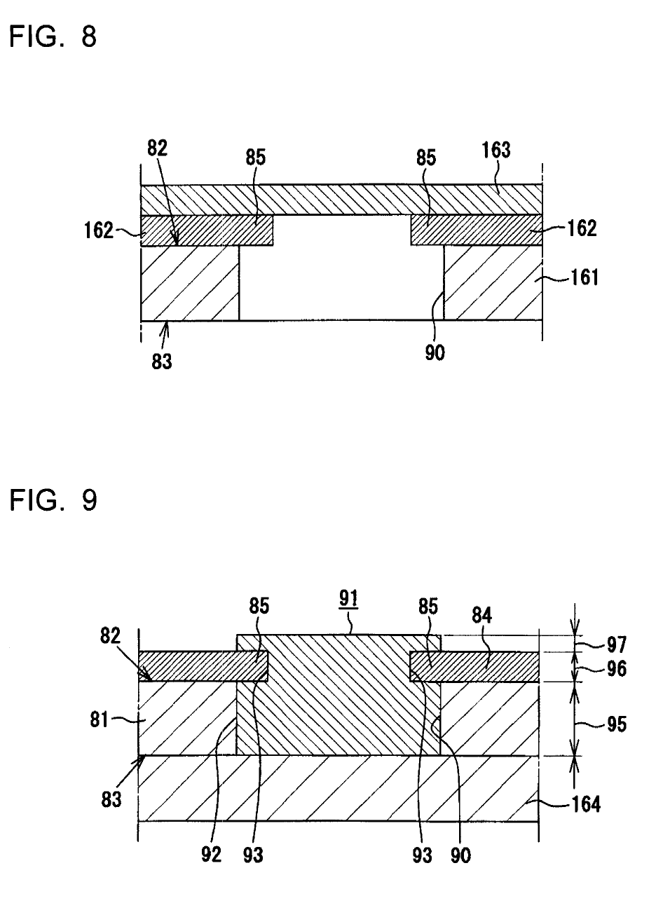

In the subsequent patterning step, the copper foil 162 is selectively removed with the projecting portions 85 left intact, so as to form the conductor layers 84. Specifically, the copper foil 162 on the first surface 82 of the resin film 161 is etched for subtractive patterning so as to form the conductor layers 84. More specifically, after electroless copper plating is performed, and using the electroless copper plating layer thus formed as a common electrode, copper electroplating is carried out. Further, a dry film 163 (RY-3325, a product of Hitachi Chemical Co., Ltd.) having a thickness of 25 μm is laminated thereon (see FIG. 8). The dry film 163 is exposed and developed, thereby forming the dry film 163 into a predetermined pattern. In this state, unnecessary (unmasked) portions of the copper electroplating layer, the electroless copper plating layer, and the copper foil 162 are removed by etching. Subsequently, the dry film 163 is removed. At this time, the conductor layers 84 are formed. Then, the surfaces of the conductor layers 84 are roughened (CZ treatment).

### (2-3) Via-Conductor-Forming Step

In a subsequent via-conductor-forming step, a silver paste is filled into the via holes 90 from the side of the first surface 82 by a known printing method which uses a printer (a product of Micro-tec Co., Ltd.), so as to form the via conductors 91 (see FIG. 9). That is, in the present embodiment, the patterning step is performed before the via-conductor-forming step. Specifically, the resin film 161 is placed on a heat-resistant acrylic tape 164 (HT-50SCBA, a product of PANAC Corp.). Next, the silver paste is filled into the via holes 90 through printing at a printing pressure of 0.15 MPa and a printing speed of 15 mm/sec by use of a printing mask (a metal mask having a thickness of 20 mm) which has openings (diameter 110 mm) at positions corresponding to the via holes 90. At this time, the silver paste projects from each of the conductor layers 84, and a projecting portion of the silver paste partially adheres to a surface of the corresponding projecting portion 85 (opposite a surface of the projecting portion 85 in contact with the first surface 82 of the conductor layer 84). Further, the silver paste partially moves toward the back surface of the projecting portion 85 and adheres to the back surface of the projecting portion 85 (a surface of the projecting portion 85 in contact with the first surface 82 of the conductor layer 84). After the thus-treated film is removed from the printer, the silver paste is heated so as to evaporate solvent and the like, and is thus solidified. Next, the silver paste is temporarily cured at a temperature of about 100° C. by applying heat for about 30 minutes. As a result, the epoxy resin of the silver paste is cured and contracted, whereby a large number of silver particles contained in the epoxy resin are pressed against each other. Thus, the via conductors 91, which are cured products of the silver paste, are formed. Subsequently, the heat-resistant acrylic tape 164 is peeled off.

### (2-4) Laminating-and-Compression-Bonding Step

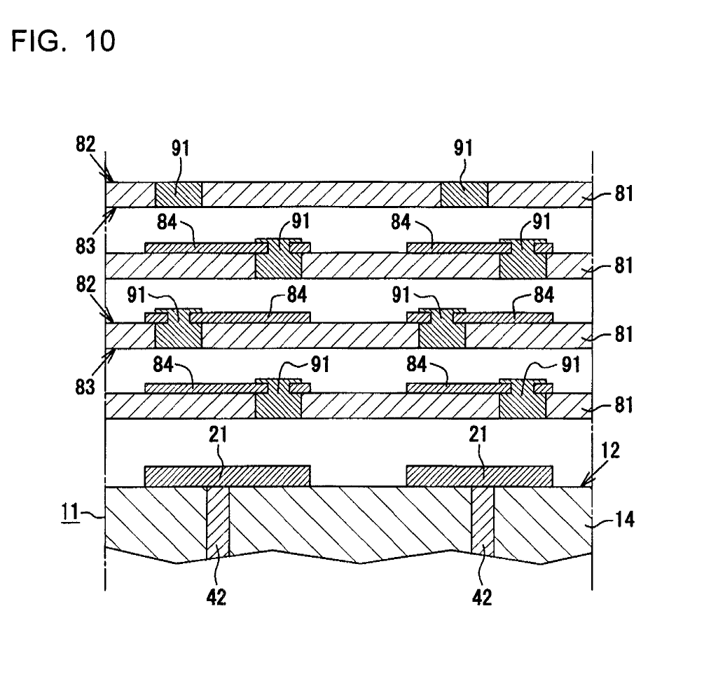

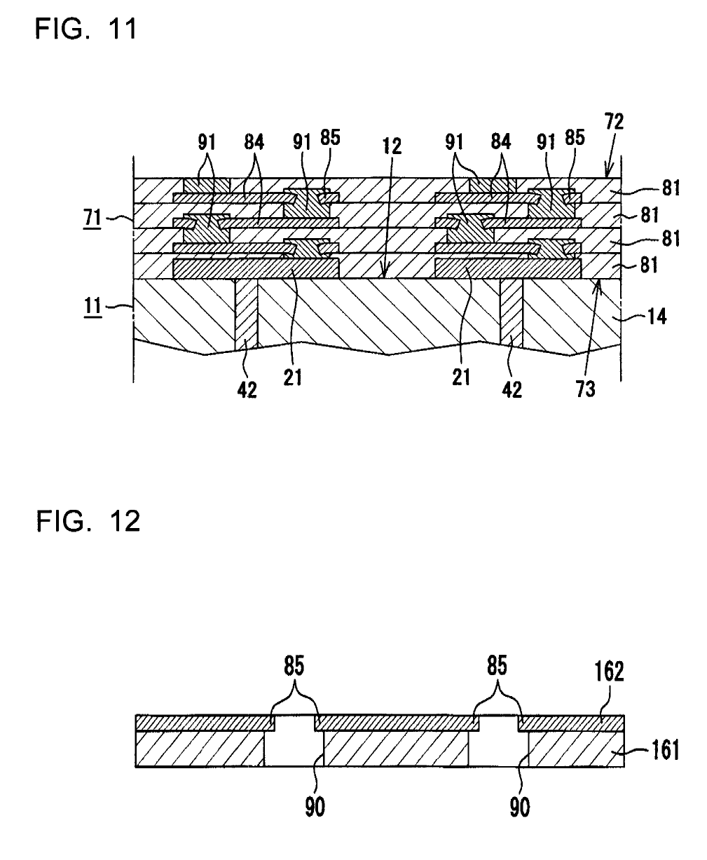

In the subsequent laminating-and-compression-bonding step, first, the ceramic multilayer wiring substrate 11 is placed on a plate-like lower jig (not shown), and the first to fourth resin dielectric layers 81 (resin films 161) are sequentially placed on the main surface 12 of the ceramic multilayer wiring substrate 11 (see FIG. 10). A plurality of positioning pins (not shown) provided on the lower jig in an extended state are caused to extend through the resin dielectric layers 81, thereby preventing horizontal movement of the resin dielectric layers 81. Subsequently, a plate-like upper jig (not shown) is placed on the laminate of the ceramic multilayer wiring substrate 11 and the four resin dielectric layers 81. Next, while the resultant assembly is heated (360° C.) under a vacuum of 2,000 Pa to 3,000 Pa or less, a pressing force (5 MPa) is applied (by a vacuum heat press) in the laminating direction (bonding direction) for one hour. By following this procedure, the ceramic multilayer wiring substrate 11 and the resin dielectric layers 81 are pressed along the laminating direction, and the heating causes plastic deformation of portions of the resin dielectric layers 81. Further, the projecting portions 85 of the conductor layers 84 are bent downward (toward the ceramic multilayer wiring substrate 11). Also, the via conductors 91 are compressed, thereby reducing a level difference between the end surfaces of the via conductors 91 located on the side of the first surface 82 and the corresponding conductor layers 84. As a result, the ceramic multilayer wiring substrate 11 and the resin dielectric layers 81 (multilayer wiring substrate 71) are bonded (thermally compression-bonded) together (see FIG. 11).

### (2-5) Main-Surface-Side-Terminal-Forming Step

After the laminating-and-compression-bonding step, the main-surface-side terminals 74, which are circular and are greater in diameter than the via conductors 91, are formed on the end surfaces of the respective via conductors 91 which are exposed at the main surface 72 of the multilayer wiring substrate 71. A specific procedure for forming the terminals 74 is described below.

First, an underlying metal layer of a one-layer structure or a multilayer structure of one or more conductive metals is formed in a central region of the main surface 72 of the multilayer wiring substrate 71 by sputtering. Next, in a state where a predetermined plating resist is applied onto the underlying metal layer, copper electroplating is carried out, thereby forming a copper plating layer. Subsequently, the plating resist is removed, followed by etching for removal of exposed portions of the underlying metal layer. As a result, a plurality of laminated metal portions each including a titanium-sputtered layer, a molybdenum-sputtered layer, and a copper plating layer are formed on the end surface of respective via conductor 91 which are exposed at the main surface 72 of the multilayer wiring substrate 71. Next, nickel electroplating is carried out so as to form nickel plating layers which cover the respective laminated metal portions. Further, gold electroplating is carried out so as to form gold plating layers which cover the respective nickel plating layers. As a result, a multilayer wiring substrate 71 having a plurality of the main-surface-side terminals 74 is completed. Thus, the substrate 10 for use in an IC inspection device is completed.

Accordingly, the present embodiment can yield the following effects.

(1) In the substrate 10 for use in an IC inspection device of the present embodiment, the projecting portions 85 of the conductor layers 84 penetrate into respective via conductors 91. Thus, individual ones of the via conductors 91 are in contact not only with an end surface of the corresponding projecting portion 85, but also a surface of the projecting portion 85 located on a side toward the main surface 72 and a surface of the projecting portion 85 located on a side toward the back surface 73. This increases the contact area between the via conductor 91 and the projecting portion 85, thereby enhancing connection reliability therebetween and in turn enhancing connection reliability of the substrate 10 for use in an IC inspection device. Since the projecting portions 85 penetrate into respective via conductors 91, the connections between the via conductors 91 and the corresponding conductive layers 84 can be reliably maintained, and durability and impact resistance are improved. For example, a problem (e.g., falling-off of the via conductor(s) 91) due to impact to the main-surface-side terminals 74 when the conductive metal probes 61 repeatedly come into contact with the main-surface-side terminals 74 can be prevented. Therefore, the life of the multilayer wiring substrate 71 and in turn the life of the substrate 10 for use in an IC inspection device can be extended. Further, since the contact areas between the via conductors 91 and the corresponding projecting portions 85 are large, the resistance of circuits composed of the via conductors 91 and the conductor layers 84 can be lowered.

(2) The substrate 10 for use in an IC inspection device of the present embodiment has a structure in which the ceramic multilayer wiring substrate 11 and the multilayer wiring substrate 71 are laminated together. Thus, the ceramic multilayer wiring substrate 11 can serve as a universal substrate (a common product), whereas the multilayer wiring substrate 71 can be customized to specific requirements of a customer. Therefore, the ceramic multilayer wiring substrates 11 can be prepared in advance. Upon receipt of an order, only the multilayer wiring substrate 71 may be manufactured. This can hasten delivery of the substrate 10 for use in an IC inspection device and allow for a shortened lead time).

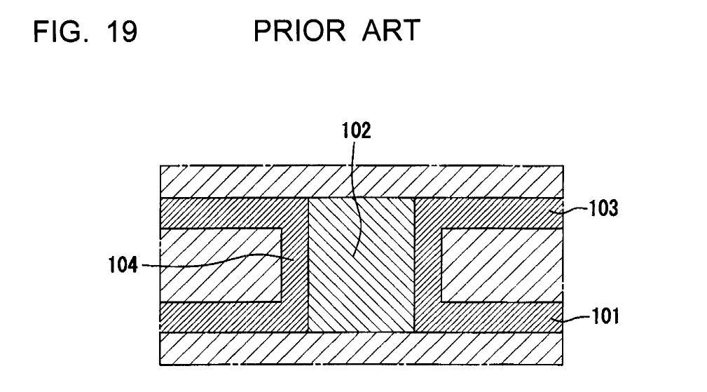

(3) According to the manufacturing method of the present embodiment, laser irradiation is performed in the drilling step, thereby forming a hole (via hole 90) extending through the resin film 161 and the copper foil 162. In contrast to conventional practice, this eliminates the need to desmear the via holes. Further, in the present embodiment, a step of forming a through-hole conductor 104 shown in FIG. 19 is not mandatory. Therefore, a process for manufacturing the multilayer wiring substrate 71 can be simplified.

The present embodiment may also be modified as described below.

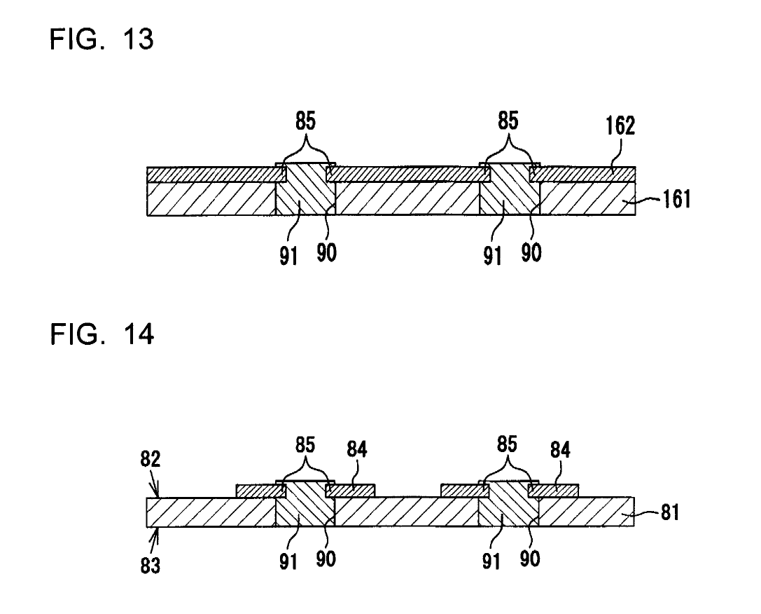

In the above-described embodiment, the patterning step is performed before the via-conductor-forming step. However, the patterning step may be performed after the via-conductor-forming step. In this case, the via-conductor-forming step is performed on the resin film 161 (see FIG. 12) in which the via holes 90 are formed and on which the projecting portions 85 of the copper foil 162 are formed, thereby forming the via conductors 91 in the respective via holes 90 (see FIG. 13). Further, the patterning step is performed so as to selectively remove the copper foil 162 with the projecting portions 85 left intact, thereby forming the conductor layers 84 (see FIG. 14).

The multilayer wiring substrate 71 of the above-described embodiment is composed of four resin dielectric layers 81, but may be composed of one to three resin dielectric layers 81, or five or more resin dielectric layers 81.

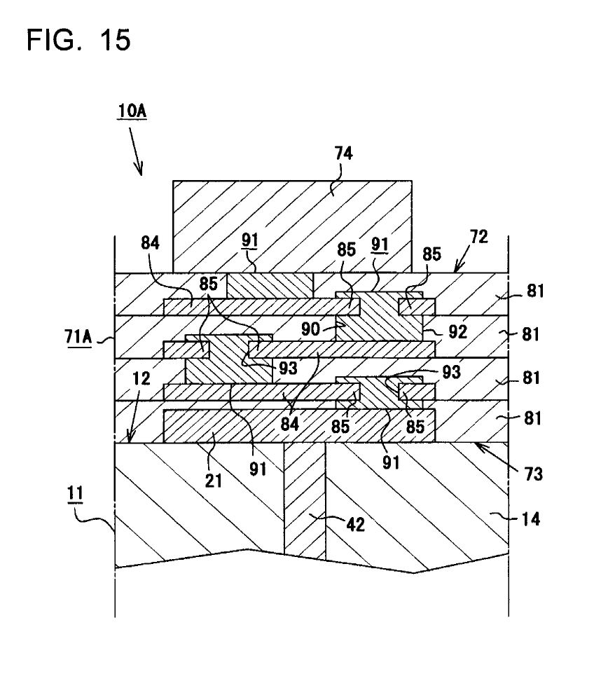

In the above-described embodiment, the projecting portions 85 of the conductor layers 84 are bent toward the back surface 73, but may be bent in the reverse direction (i.e., toward the main surface 72). Alternatively, as in the case of a multilayer wiring substrate 71A in a substrate 10A for use in an IC inspection device according to another embodiment of the present invention shown in FIG. 15, the projecting portions 85 of the conductor layers 84 may be bent neither toward the main surface 72 nor toward the back surface 73, but may be straight (i.e., may project horizontally in a level manner). This can be implemented, for example, by setting a pressing force to be applied in the laminating-and-compression-bonding step that is slightly smaller than that used in the above-described embodiment.

Even in such embodiment, the projecting portions 85 of the conductor layers 84 are fitted into the groove portions 93 of the respective via conductors 91. Thus, individual ones of the via conductors 91 can be in contact with an end surface of the corresponding projecting portion 85, a surface of the projecting portion 85 located on a side toward the main surface, and a surface of the projecting portion 85 located on a side toward the back surface. This increases the contact area between the via conductor 91 and the projecting portion 85, thereby enhancing connection reliability. Also, since the projecting portions 85 are fitted into the groove portions 93 of the respective via conductors 91, the connections between the via conductors 91 and the corresponding conductive layers 84 can be reliably maintained, and durability and impact resistance are improved. Therefore, the life of the ceramic multilayer wiring substrate 11 can be extended. Further, since the contact area between the via conductors 91 and the corresponding projecting portions 85 is large, the resistance of circuits composed of the via conductors 91 and the conductor layers 84 can be lowered.

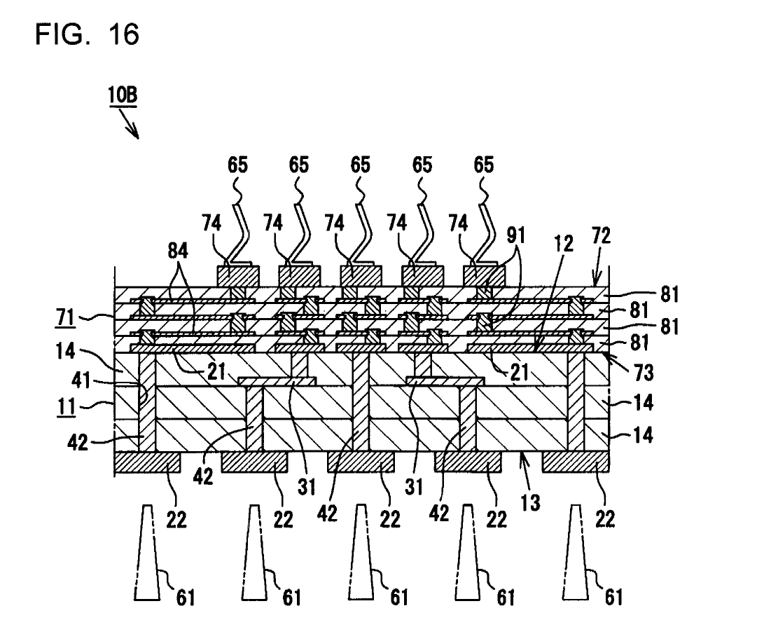

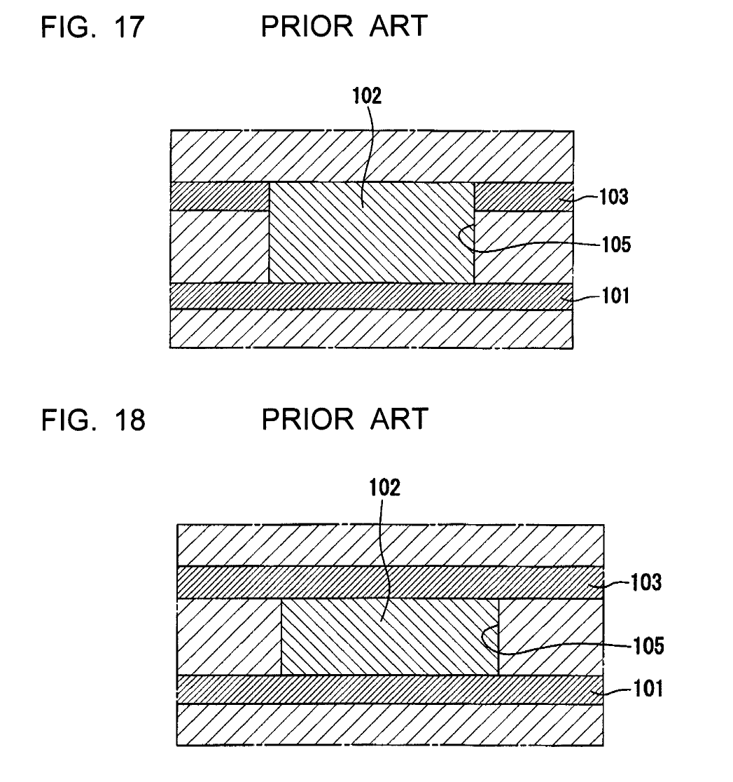

FIG. 16 shows a schematic configuration of a substrate 10B for use in an IC inspection device according to a further embodiment of the present invention. In substrate 10B for use in an IC inspection device, a plurality of the conductive metal probes 61 are disposed on the side of the back surface 13 of the ceramic multilayer wiring substrate 11, and not on the side of the main surface 12. A plurality of the conductive metal probes 61 mechanically comes into contact with a plurality of the back-surface-side terminals 22, respectively. In FIG. 16, in place of the conductive metal probes 61, a plurality of probe pins 65 of a conductive metal are attached to a plurality of the mains-surface-side terminals 74, respectively, and are adapted to come into contact with respective terminals of an IC.

According to the above-mentioned configuration, impact tends to be repeatedly applied to the main-surface-side terminals 74 through the respective probe pins 65 which come into contact with an IC. However, since the projecting portions 85 penetrate into the via conductors 91, falling-off of the via conductor(s) 91 or a like problem can be prevented. Therefore, the life of the multilayer wiring substrate 71 and in turn the life of the substrate 10B for use in an IC inspection device can be extended.

The above-described embodiments may be implemented in a multilayer wiring substrate of the invention, which has a main surface and a back surface and in which a plurality of main-surface-side terminals are formed on the main surface, the multilayer wiring substrate comprising: one or more resin dielectric layers individually having a first surface and a second surface and having via holes formed therein and extending through the first surface and the second surface; conductor layers formed from a conductive metal material and disposed on at least one of the first surface and the second surface of the individual resin dielectric layers; via conductors disposed in the respective via holes, formed from a cured product of a conductive metal paste or an agglomerate of conductive metal particles, and electrically connected to respective conductor layers; and projecting portions of the conductor layers, the projecting portions being bent toward the main surface or the back surface, and projecting from opening edges of the respective via holes toward center axes thereof, and penetrating into side surfaces of the respective via conductors.

It should further be apparent to those skilled in the art that various changes in form and detail of the invention as shown and described above may be made. It is intended that such changes be included within the spirit and scope of the claims appended hereto.

This application is based on Japanese Patent Application No. 2007-219073 filed Aug. 24, 2007, incorporated herein by reference in is entirety.

What is claimed is:

1. A multilayer wiring substrate which has a main surface and a back surface and in which a plurality of main-surface-side terminals are formed on the main surface, comprising:
one or more resin dielectric layers individually having a first surface and a second surface and having via holes formed therein and extending through the first surface and the second surface;
conductor layers formed from a conductive metal material and disposed on at least one of the first surface and the second surface of the one or more resin dielectric layers; and
via conductors disposed in respective via holes and electrically connected to respective conductor layers,
wherein the conductor layers have projecting portions that are bent toward the main surface or the back surface, said projecting portions projecting from opening edges of the respective via holes toward center axes thereof and penetrating into the respective via conductors.

2. A multilayer wiring substrate which has a main surface and a back surface and in which a plurality of main-surface-side terminals are formed on the main surface, comprising:
one or more resin dielectric layers individually having a first surface and a second surface and having via holes formed therein and extending through the first surface and the second surface;
conductor layers formed from a conductive metal material and disposed on at least one of the first surface and the second surface of the one or more resin dielectric layers; and
via conductors disposed in respective via holes and electrically connected to respective conductor layers,
wherein the conductor layers have projecting portions that are bent toward the main surface or the back surface, said projecting portions projecting from opening edges of the respective via holes toward center axes thereof, and
wherein the via conductors have respective groove portions on their side surfaces, and the projecting portions of the conductor layers are fitted into the respective groove portions.

3. The multilayer wiring substrate according to claim 1, wherein the projecting portions penetrate into the side surfaces of the respective via conductors along an entire circumference thereof.

4. The multilayer wiring substrate according to claim 2, wherein the projecting portions penetrate into the side surfaces of the respective via conductors along an entire circumference thereof.

5. The multilayer wiring substrate according to claim 1, wherein the via conductors have flat end surfaces located opposite a side toward which the projecting portions of the conductor layers are bent.

6. The multilayer wiring substrate according to claim 2, wherein the via conductors have flat end surfaces located opposite a side toward which the projecting portions of the conductor layers are bent.

7. The multilayer wiring substrate according to claim 1, wherein individual ones of the via conductors comprise a primary large-diameter portion disposed in a corresponding via hole and a secondary large-diameter portion connected together via a small-diameter portion, and
the primary large-diameter portion and the secondary large-diameter portion hold a corresponding projecting portion of the conductor layer therebetween across a thickness direction of the projecting portion.

8. The multilayer wiring substrate according to claim 2, wherein individual ones of the via conductors comprise a primary large-diameter portion disposed in a corresponding via hole and a secondary large-diameter portion connected together via a small-diameter portion, and
the primary large-diameter portion and the secondary large-diameter portion hold a corresponding projecting portion of the conductor layer therebetween across a thickness direction of the projecting portion.

9. A multilayer wiring substrate which has a main surface and a back surface and in which a plurality of main-surface-side terminals are formed on the main surface, comprising:
one or more resin dielectric layers individually having a first surface and a second surface and having via holes formed therein and extending through the first surface and the second surface;
conductor layers formed from a conductive metal material and disposed on at least one of the first surface and the second surface of the one or more resin dielectric layers; and
via conductors disposed in respective via holes and electrically connected to respective conductor layers,
wherein the conductor layers have projecting portions projecting from opening edges of the respective via holes toward center axes thereof, and
wherein the via conductors have respective groove portions on their side surfaces, and the projecting portions of the conductor layers are fitted into the respective groove portions.

10. A substrate for use in an IC inspection device, comprising the multilayer wiring substrate described in claim 1, and a ceramic multilayer wiring substrate bonded to a back surface of the multilayer wiring substrate for supporting the multilayer wiring substrate, and electrically connected to the multilayer wiring substrate, the substrate being configured such that a plurality of conductive metal probes can repeatedly come into contact with the plurality of main-surface-side terminals, respectively, of the multilayer wiring substrate.

11. A substrate for use in an IC inspection device, comprising the multilayer wiring substrate described in claim 2, and a ceramic multilayer wiring substrate bonded to a back surface of the multilayer wiring substrate for supporting the multilayer wiring substrate, and electrically connected to the multilayer wiring substrate, the substrate being configured such that a plurality of conductive metal probes can repeatedly come into contact with the plurality of main-surface-side terminals, respectively, of the multilayer wiring substrate.

12. A substrate for use in an IC inspection device, comprising the multilayer wiring substrate described in claim 1; a ceramic multilayer wiring substrate bonded to a back surface of the multilayer wiring substrate for supporting the multilayer wiring substrate, and electrically connected to the multilayer wiring substrate; and a plurality of probe pins formed from a conductive metal, attached to the plurality of main-surface-side terminals, respectively, of the multilayer wiring substrate, and adapted to make contact with respective terminals of an IC.

13. A substrate for use in an IC inspection device, comprising the multilayer wiring substrate described in claim 2; a ceramic multilayer wiring substrate bonded to a back surface of the multilayer wiring substrate for supporting the multilayer wiring substrate, and electrically connected to the multilayer wiring substrate; and a plurality of probe pins formed from a conductive metal, attached to the plurality of main-surface-side terminals, respectively, of the multilayer wiring substrate, and adapted to make contact with respective terminals of an IC.

14. A method for manufacturing a multilayer wiring substrate described in claim 1, comprising:
drilling via holes through a resin film having a first surface and a second surface, the first surface being clad with a metal foil, and forming projecting portions of the metal foil projecting from opening edges of the respective via holes toward center axes thereof, by irradiating the resin film with a laser beam from a side of the second surface;
selectively removing the metal foil with the projecting portions left intact, so as to form patterned conductor layers;
filling a conductive metal paste into the via holes from a side of the first surface so as to form via conductors; and
laminating a plurality of the resin films which have undergone the via-conductor-forming step, and compression-bonding the plurality of the resin films.

15. The method for manufacturing a multilayer wiring substrate according to claim 14, wherein the patterning step is carried out before the via-conductor-forming step.

16. The method for manufacturing a multilayer wiring substrate according to claim 14, wherein the metal foil comprises a copper foil, and the conductive metal paste comprises a silver paste.

17. A method for manufacturing a multilayer wiring substrate according to claim 14, wherein, in laser irradiation of the drilling step, the laser beam is focused on a position located short of the second surface of the resin film.

18. A method for manufacturing a substrate for use in an IC inspection device described in claim 10, comprising:
drilling via holes through a resin film having a first surface and a second surface, the first surface being clad with a metal foil, and forming projecting portions of the metal foil projecting from opening edges of the respective via holes toward center axes thereof, by irradiating the resin film with a laser beam from a side of the second surface;
selectively removing the metal foil with the projecting portions left intact, so as to form patterned conductor layers;
filling a conductive metal paste into the via holes from a side of the first surface so as to form via conductors; and
laminating a plurality of the resin films which have undergone the via-conductor-forming step, on a main surface of a ceramic multilayer wiring substrate, and compression-bonding the plurality of the resin films and the ceramic multilayer wiring substrate.
